(19) United States
(12) Patent Application Publication
(10) Pub. No.: US 2012/0161853 A1
(43) Pub. Date: Jun. 28, 2012

(54) CIRCUIT AND METHOD FOR TEMPERATURE COMPENSATION OF A SENSOR

(75) Inventor: Chun-Yu TAI, New Taipei City (TW)

(73) Assignee: British Virgin Islands Central Digital Inc.

(21) Appl. No.: 13/335,258

(22) Filed: Dec. 22, 2011

(30) Foreign Application Priority Data
Dec. 28, 2010 (TW) 099146238

(51) Int. Cl. H01L 35/00

(52) U.S. Cl. 327/513

(57) ABSTRACT

A circuit for temperature compensation is connected to a sensor. The circuit includes an impedance element and a voltage controller. The impedance element has one terminal connected to a second terminal of the sensor, and the other terminal connected to a low voltage source. The voltage controller has an input terminal connected to the second terminal of the sensor to receive a to-be-measured voltage, a reference terminal receiving a reference voltage, and an output terminal is connected to the first terminal of the sensor to adjust a voltage level of the high voltage source. When the sensor output voltage varies due to change of an environment temperature, the voltage controller compares the reference voltage with the varied to-be-measured voltage to adjust the voltage level of the high voltage source, thereby restoring the varied sensor output voltage to a voltage level before being varied.

### CROSS-REFERENCE TO RELATED APPLICATIONS

This non-provisional application claims priority under 35 U.S.C. §119(a) on Patent Application No(s). 099146238 filed in Taiwan, R.O.C. on Dec. 28, 2010, the entire contents of which are hereby incorporated by reference.

### BACKGROUND

1. Technical Field

The present disclosure relates to a circuit and a method for temperature compensation of a sensor, and more particularly to a circuit and a method for temperature compensation of a sensor which perform compensation for output variation generated due to change of an environment temperature.

2. Related Art

With the advance of science and technology, more and more sensors are designed and developed. There are various sensors, such as such as pressure sensors, temperature sensors, gas sensors, sound sensors, brightness sensors, speed sensors, and image sensors. Sensors are also widely used in various fields, such as, medical apparatus, public transportation vehicle, safety detection, entertainment, national defense, and so on.

FIG. 1 is a schematic view of a conventional sensor. In FIG. 1, a sensor 10 has an input terminal, a grounding terminal and an output terminal. The input terminal is electrically connected to a constant voltage source Vcc. the grounding terminal is electrically connected to the ground GND, and the output terminal is used to provide a sensor output voltage Vs.

One of features of the sensor is in that, the output voltage Vs varies with an environment temperature due to the internal resistance of the sensor varying as the environment temperature changes. For example, the output voltage Vs of some sensors increases as the environment temperature changes (implying that the sensors have a positive temperature coefficient), while the output voltage Vs of some sensors decreases as the environment temperature changes (implying that the sensors have a negative temperature coefficient).

If a sensor is regarded as a resistor, it is known according to Ohm's law V=I*R that, when the constant voltage source Vcc is invariable, if the internal resistance of the sensor 10 varies, because the internal resistance of the sensor 10 is inversely proportional to the current I passing through the sensor 10, the current I passing through the sensor 10 is also accordingly varied. In such case, the current I passing through the sensor 10 will influence the output voltage Vs of the sensor 10.

FIG. 2 is a schematic diagram for a practical circuit of a conventional sensor d. An amplifier circuit 20 and a processor circuit 30 are further sequentially connected in series at an output terminal of the sensor 10.

In a current system using a sensor, in order to improve preciseness, temperature compensation measures are generally implemented for the sensor for avoiding the problems caused from the variation of the environment temperature. The measures include two types: (1) by use of a hardware line to perform temperature compensation, and (2) by use of a hardware line in cooperation with software temperature compensation. The two types are respectively described as follows:

(1) By use of a hardware line to perform temperature compensation:

In the amplifier circuit 20 connecting behind the sensor output terminal, elements having temperature features such as a thermistor or temperature sensor are added to the loop of the amplifier circuit 20 to automatically adjust the gain factor.

(2) By use of a hardware line in cooperation with the software temperature:

Elements having temperature features such as a thermistor or temperature sensor are added to the system to sense the environment temperature, and then the processor circuit 30 compensates the temperature offset.

However, the two temperature compensation manners for the conventional sensor both have disadvantages. First, the circuit structure of the former one is complex and requires correction; and although the circuit structure of the latter one is simple, the offset needs to be corrected for each temperature point, which is very time-consuming.

For these reasons, it is desirous to provide a circuit and a method for temperature compensation of a sensor performing compensation for the output variation generated due to the change of the environment temperature so as to avoid deficiency of the temperature compensation manners for the conventional sensor.

### SUMMARY

The present disclosure is a circuit and a method for temperature compensation of a sensor. The circuit structure is simple, and the offset of each temperature point does not require correction. Thus the operating performance of the sensor is effectively improved.

In one embodiment, the present disclosure provides a circuit with temperature compensation, which comprises: a sensor, having a first terminal, a second terminal and an output terminal, in which the first terminal is electrically connected to a high voltage source, the second terminal generates a to-be-measured voltage, and the output terminal provides a sensor output voltage; an impedance element, having two terminals, in which one terminal is electrically connected to the second terminal of the sensor, and the other terminal is electrically connected to a low voltage source; and a voltage controller, having an input terminal, a reference terminal and an output terminal, in which the input terminal is electrically connected to the second terminal of the sensor to receive the to-be-measured voltage, the reference terminal receives a reference voltage, and the output terminal is electrically connected to the first terminal of the sensor to adjust a voltage level of the high voltage source. When the sensor output voltage varies due to change of an environment temperature, the to-be-measured voltage of the second terminal of the sensor also varies accordingly, and the voltage controller compares the reference voltage with the varied to-be-measured voltage, so as to adjust the voltage level of the high voltage source, thereby enabling the varied sensor output voltage to be restored to a voltage level of the sensor output voltage before being varied.

In another embodiment, the present disclosure provides a method for temperature compensation of a sensor. The sensor in this embodiment has a first terminal, a second terminal and an output terminal; the first terminal is electrically connected to a high voltage source, the second terminal generates a to-be-measured voltage, the output terminal provides a sensor output voltage. The method for temperature compensation of a sensor comprises the following steps: providing an impedance element, in which one terminal of the impedance element is electrically connected to the second terminal of the sensor, and the other terminal of the impedance element is electrically connected to a low voltage source; and providing a reference voltage, in which when the sensor output voltage is varied due to change of an environment temperature, the to-be-measured voltage of the second terminal of the sensor is also accordingly varied, the reference voltage is compared with the varied to-be-measured voltage, so as to adjust a voltage level of the high voltage source, thereby enabling the varied sensor output voltage to be restored to a voltage level of the sensor output voltage before being varied.

According to the embodiments, the high voltage source is a controlled voltage source.

According to the embodiments, the low voltage source is connected to a connected to a ground.

According to the embodiments, the impedance element is a resistor.

According to the embodiments the voltage controller is a comparator.

According to the embodiments, the voltage controller is a microprocessor, and the microprocessor has an analog-digital-analog conversion function.

According to the embodiments, the voltage controller is an adjustable low-dropout regulator (LDO Regulator).

### BRIEF DESCRIPTION OF THE DRAWINGS

The present disclosure will become more fully understood from the detailed description given herein below for illustration only, and thus are not limitative of the present disclosure, and in which:

FIG. 1 is a schematic view of a conventional sensor;

FIG. 2 is a schematic diagram for a practical circuit of a conventional sensor; and

FIG. 3 is a block view of a circuit for temperature compensation of a sensor according to the present disclosure.

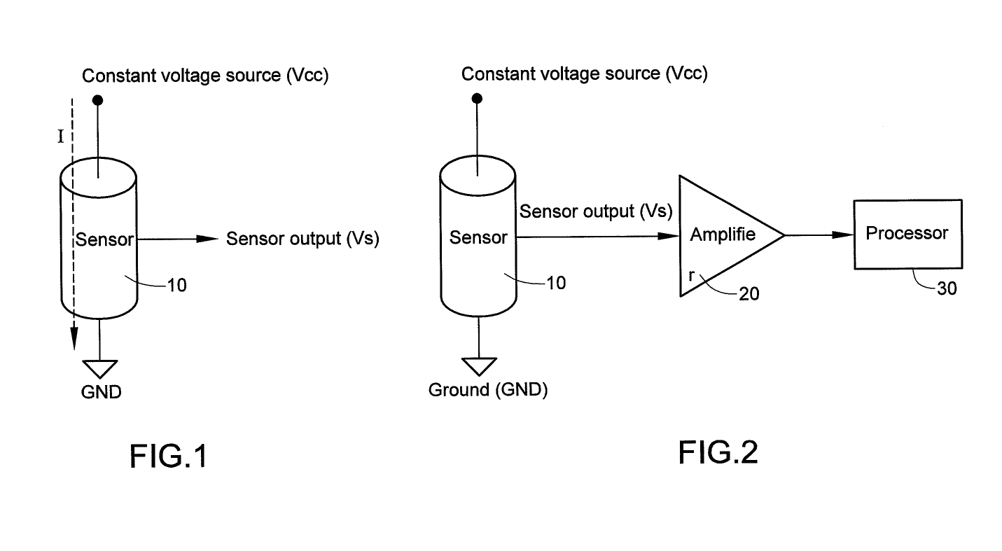

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

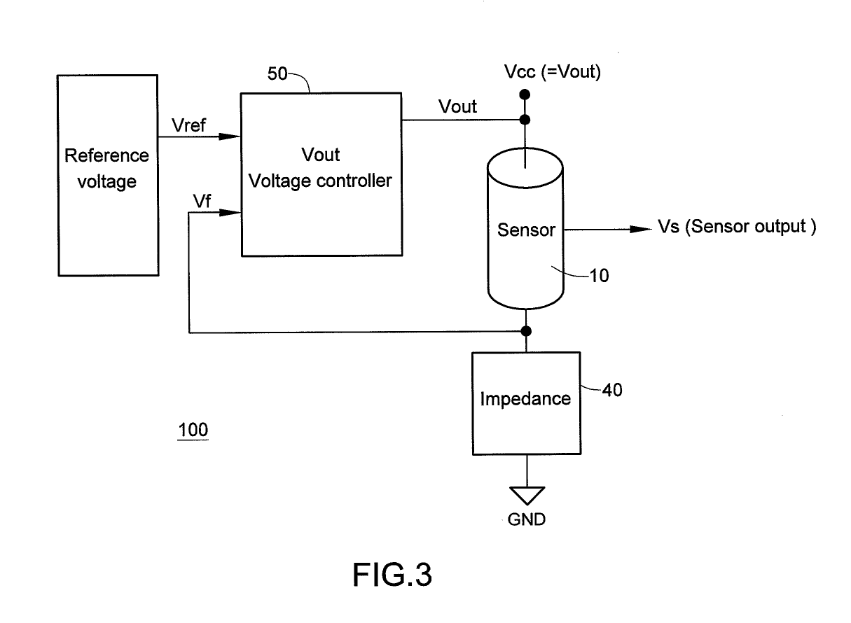

FIG. 3 shows a block view of a circuit with temperature compensation according to the present disclosure. In FIG. 3, a sensor 10, an impedance element 40 and a voltage controller 50 constitutes the circuit 100 with temperature compensation. The compensation circuit in circuit 100 includes impedance element 40 and a voltage controller 50.

The sensor 10, connecting to the compensation circuit, has a first terminal, a second terminal and an output terminal. The first terminal is electrically connected to a high voltage source Vcc, the second terminal generates a to-be-measured voltage Vf, and the output terminal provides a sensor output voltage Vs.

The impedance element 40 has two terminals, wherein one terminal is electrically connected to the second terminal having the to-be-measured voltage Vf of the sensor 10, and the other terminal is electrically connected to a low voltage source. In this embodiment, the low voltage source is connected to a ground.

The voltage controller 50 has an input terminal, a reference terminal and an output terminal. The input terminal is electrically connected to the second terminal of the sensor 10 to receive the to-be-measured voltage Vf. The reference terminal receives a reference voltage Vref. The output terminal is electrically connected to the first terminal of the sensor 10 to adjust a voltage level of the high voltage source Vcc. The adjusted voltage level of the high voltage source Vcc is denoted with Vout, in which the value Vcc definitely is equal to Vout itself being the working voltage of the sensor 10.

Technical characteristics of the circuit for temperature compensation of a sensor according to the disclosure are as follows. When the environment temperature of the sensor 10 does not change, that is, in a constant temperature state, the value of the reference voltage Vref is equal to the value of the to-be-measured voltage Vf. However, when the sensor 10 changes due to the environment temperature, the internal resistance of the sensor 10 also changes; according to the voltage division rule, the to-be-measured voltage Vf of the second terminal of the sensor 10 also varies accordingly varied, and the sensor output voltage Vs also varies.

In order to compensate variation of the sensor output voltage Vs, in this disclosure, the voltage controller 50 compares the reference voltage Vref with the varied to-be-measured voltage Vf. When it can be perceived through the comparison program detects the difference between the value of the reference voltage Vref and the value of the to-be-measured voltage Vf, the voltage controller 50 adjusts the voltage level of the high voltage source Vcc. Based on the voltage division rule, the value of the to-be-measured voltage Vf becomes the same as the value of the reference voltage Vref again.

The voltage automatic control method described above may enable the varied sensor output voltage Vs restore to a voltage level of the sensor output voltage Vs before being varied, so as to procure the objective of performing temperature compensation on the sensor 10.

In the circuit 100 for temperature compensation of a sensor according to this embodiment, the high voltage source Vcc is a controlled voltage source, and the impedance element 40 is a resistor, and may also be an equivalent resistor formed of impedance elements of enormous elements.

Furthermore, in the circuit 100 for temperature compensation of a sensor according to this application, the voltage controller 50 may be manufactured with a comparator, and may also be manufactured with a microprocessor, and the microprocessor needs to have an analog-digital-analog conversion function. Moreover, the voltage controller 50 may also be an adjustable low-dropout regulator (LDO Regulator). With respect to persons skilled in the art, the voltage controller 50 may be formed with various conventional devices or methods, as long as the objective intended to be achieved by the circuit and the method for temperature compensation of a sensor according to the present disclosure is achieved.

To sum up, the present disclosure proposes a circuit and a method for temperature compensation of a sensor. The circuit structure is not only simple, but also the offset of each temperature point does not require correction, thereby effectively improving operating performance of the sensor, and reducing the production working hours and the cost.

What is claimed is:

1. A circuit having temperature compensation, comprising:
a sensor, having a first terminal, a second terminal and an output terminal, wherein the first terminal is electrically connected to a high voltage source, the second terminal generates a to-be-measured voltage, and the output terminal provides a sensor output voltage;
an impedance element, having two terminals, wherein one terminal is electrically connected to the second terminal of the sensor, and the other terminal is electrically connected to a low voltage source; and
a voltage controller, having an input terminal, a reference terminal and an output terminal, wherein the input terminal is electrically connected to the second terminal of the sensor to receive the to-be-measured voltage, the reference terminal receives a reference voltage, the output terminal is electrically connected to the first terminal of the sensor to adjust a voltage level of the high voltage source,
wherein, when the sensor output voltage varies due to change of an environment temperature, the to-be-measured voltage of the second terminal of the sensor also varies accordingly, and the voltage controller compares the reference voltage with the varied to-be-measured voltage, so as to adjust the voltage level of the high voltage source, thereby restoring the varied sensor output voltage to a voltage level of the sensor output voltage before being varied.

2. The circuit according to claim 1, wherein the high voltage source is a controlled voltage source.

3. The circuit according to claim 1, wherein the low voltage source is connected to a ground.

4. The circuit according to claim 1, wherein the impedance element is a resistor.

5. The circuit according to claim 1, wherein the voltage controller is a comparator.

6. The circuit according to claim 1, wherein the voltage controller is a microprocessor, and the microprocessor has an analog-digital-analog conversion function.

7. The circuit according to claim 1, wherein the voltage controller is an adjustable low-dropout regulator (LDO Regulator).

8. A method for temperature compensation of a sensor, wherein the sensor has a first terminal, a second terminal and an output terminal, the first terminal is electrically connected to a high voltage source, the second terminal generates a to-be-measured voltage, the output terminal provides a sensor output voltage, and the method comprises the following steps:
providing an impedance element, wherein one terminal of the impedance element is electrically connected to the second terminal of the sensor, and the other terminal of the impedance element is electrically connected to a low voltage source; and
providing a reference voltage, wherein
when the sensor output voltage varies due to change of an environment temperature, the to-be-measured voltage of the second terminal of the sensor also varies accordingly, and the reference voltage is compared with the varied to-be-measured voltage, so as to adjust a voltage level of the high voltage source, thereby restoring the varied sensor output voltage to a voltage level of the sensor output voltage before being varied.

9. The method according to claim 8, wherein a controlled voltage source is used as the high voltage source.

10. The method according to claim 8, wherein ground is used as the low voltage source.

11. The method according to claim 8, wherein a resistor is used as the impedance element.
